(19) United States
(12) Patent Application Publication
(10) Pub. No.: US 2025/0283843 A1
(43) Pub. Date: Sep. 11, 2025

(54) NUCLEAR MAGNETIC RESONANCE APPARATUS

(71) Applicant: AISIN CORPORATION, Kariya (JP)

(72) Inventors: Toshihiko ISHIDA, Kariya-shi (JP); Yasunori KAWAI, Kariya-shi (JP)

(73) Assignee: AISIN CORPORATION, Kariya (JP)

(21) Appl. No.: 19/073,382

(22) Filed: Mar. 7, 2025

(30) Foreign Application Priority Data
Mar. 11, 2024 (JP) 2024-036760

(51) Int. Cl. G01N 24/08; G01R 33/30

(52) U.S. Cl. CPC G01N 24/08; G01R 33/30

(57) ABSTRACT

A nuclear magnetic resonance apparatus including a magnetic field generator generating a magnetic field, a sample container held in the generated magnetic field and containing a sample to be analyzed, a probe that emits an electromagnetic wave at the sample and detects a nuclear magnetic resonance signal from the sample, a first protective cover surrounding a space where a strength of the generated magnetic field is equal to or greater than a first threshold, a second protective cover mounted outside the first protective cover and surrounding a space where the strength of the generated magnetic field is equal to or greater than a second threshold is weaker than the first threshold, an opening provided in the second protective cover, and a probe adjuster disposed outside the first protective cover and inside the second protective cover in vicinity of the opening to adjust a characteristic of the probe by an operator.

### CROSS REFERENCE TO RELATED APPLICATIONS

This application is based on and claims priority under 35 U.S.C. § 119 to Japanese Patent Application No. 2024-036760, filed on Mar. 11, 2024, the entire content of which is incorporated herein by reference.

### TECHNICAL FIELD

This disclosure relates to a nuclear magnetic resonance apparatus including a magnetic field generator.

### BACKGROUND DISCUSSION

Conventionally, various analysis techniques and image diagnosis techniques using nuclear magnetic resonance (NMR) have been put into practical use. Nuclear magnetic resonance is a phenomenon in which, when an electromagnetic wave is emitted from outside at an atomic nucleus to which a magnetic field is applied, the atomic nucleus absorbs a specific electromagnetic wave corresponding to each chemical environment. Examples of a nuclear magnetic resonance apparatus utilizing these nuclear magnetic resonance phenomena include a nuclear magnetic resonance analysis apparatus (NMR analysis apparatus) that utilizes nuclear magnetic resonance phenomena to analyze structures of samples, a magnetic resonance imaging apparatus (MRI apparatus) that utilizes nuclear magnetic resonance phenomena to image information of an inside of a living body, and the like.

These nuclear magnetic resonance apparatuses (hereinafter, abbreviated as an NMR apparatus) internally include a device called a probe as a mechanism for emitting the above-described electromagnetic wave and detecting a nuclear magnetic resonance signal indicating an amount of energy absorbed due to a nuclear magnetic resonance phenomenon. In order to accurately analyze a sample, it is necessary to individually adjust (tune) a characteristic of the probe according to an installed NMR apparatus. Therefore, conventionally, as disclosed in JP 2023-061460 A, a probe includes an operation unit for adjusting characteristics, and an operator adjusts a characteristic of the probe by operating the operation unit.

Here, as a part thereof, the NMR apparatus includes a magnetic field generator that generates a magnetic field. However, with an NMR apparatus in particular, sensitivity and resolution of a signal are higher as the generated magnetic field is stronger. Therefore, it is desired that the NMR apparatus includes a magnetic field generator that generates a strong magnetic field. However, if such a magnetic field generator that generates a strong magnetic field is provided, as in JP 2023-061460 A (paragraph 0044, FIG. 4), when an operation unit included in a probe is operated to adjust a characteristic of the probe, a metal object worn or possessed by an operator who operates the operation unit may be attracted, or malfunction of a precision instrument may be caused.

A need thus exists for a nuclear magnetic resonance apparatus which is not susceptible to the drawback mentioned above.

### SUMMARY

A nuclear magnetic resonance apparatus includes a magnetic field generator that generates a magnetic field, a sample container that is held in a magnetic field generated by the magnetic field generator and contains a sample to be analyzed, a probe that emits an electromagnetic wave at the sample and detects a nuclear magnetic resonance signal from the sample, a first protective cover that surrounds at least a space in which strength of a magnetic field generated by the magnetic field generator is equal to or greater than a first threshold value, a second protective cover that is mounted outside of the first protective cover and surrounds at least a space in which strength of a magnetic field generated by the magnetic field generator is equal to or greater than a second threshold value that is weaker than the first threshold value, an opening provided in the second protective cover, and a probe adjuster that is disposed outside the first protective cover and inside the second protective cover, and in vicinity of the opening, and adjusts a characteristic of the probe by receiving operation by an operator.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is an external view showing an entire NMR analysis apparatus according to the present embodiment;

FIG. 2 is an external view showing the entire NMR analysis apparatus in a state where protective covers covering outside of the NMR analysis apparatus are removed;

FIG. 3 is a cross-sectional view showing a periphery of a main body of the NMR analysis apparatus in particular;

FIG. 4 is a view showing a state in which a probe is fitted to a storage container;

FIG. 5 is a view showing the probe and a probe adjuster;

FIG. 6 is an external view showing appearance of a stay;

FIG. 7 is a view showing spaces surrounded by strong-magnetic-field protection members and weak-magnetic-field protection members;

FIG. 8 is a view showing vicinity of an opening of the main body in a state where an opening and closing door is open;

FIG. 9 is a diagram showing an example of a dial of the probe adjuster; and

FIG. 10 is a diagram showing a schematic configuration of the NMR analysis apparatus.

### DETAILED DESCRIPTION

Hereinafter, a nuclear magnetic resonance apparatus according to an embodiment of this disclosure will be described in detail with reference to the drawings. Hereinafter, as the nuclear magnetic resonance apparatus, a nuclear magnetic resonance analysis apparatus (hereinafter, referred to as an NMR analysis apparatus) that analyzes a structure of a sample by using a nuclear magnetic resonance phenomenon in particular will be described as an example.

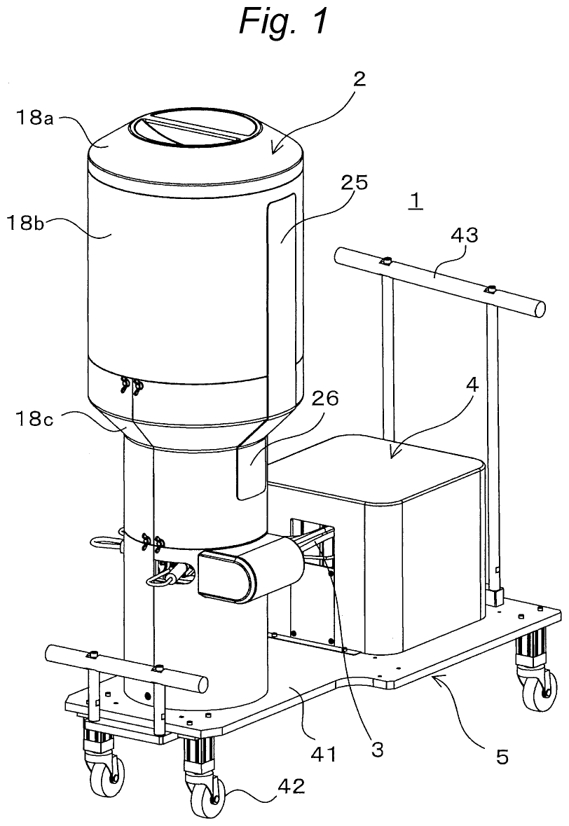

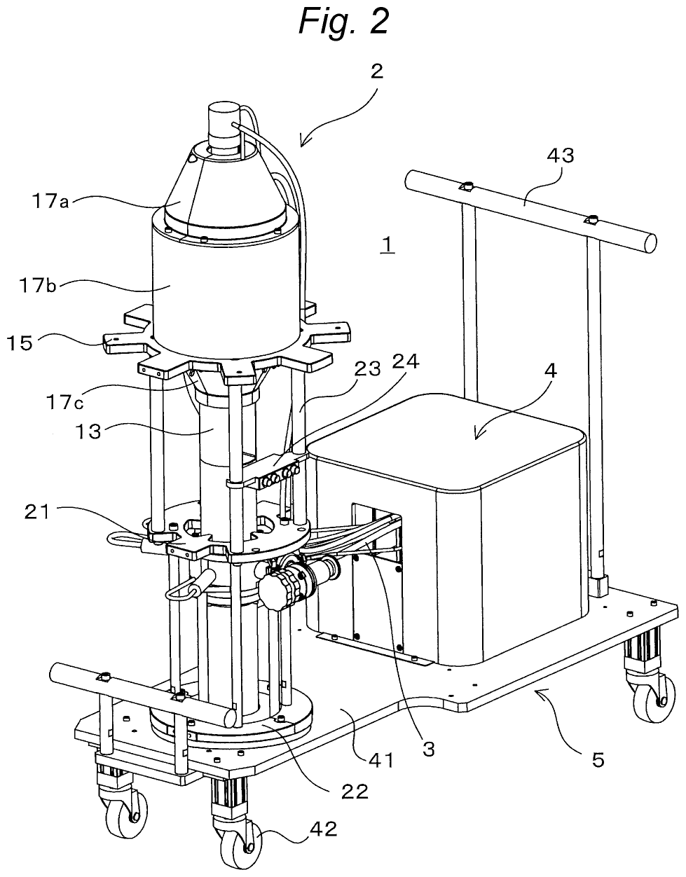

First, a schematic configuration of an NMR analysis apparatus 1 according to the present embodiment will be described with reference to FIGS. 1 and 2. FIG. 1 is an external view showing the entire NMR analysis apparatus 1 according to the present embodiment, and FIG. 2 is an external view showing the entire NMR analysis apparatus 1 in a state where protective covers (weak-magnetic-field protection members 18a to 18c described later) particularly covering outside of the NMR analysis apparatus 1 are removed.

As shown in FIGS. 1 and 2, the NMR analysis apparatus 1 according to the present embodiment basically includes a main body 2 internally including a sample container that contains a sample to be analyzed, a probe for analyzing the sample, and a superconductor (magnetic field generator) for generating a static magnetic field in the main body 2, an external device 4 connected to the main body 2 through a pipe 3 or a cable and including a compressor that supplies a refrigerant for cooling the superconductor in the main body 2, a pump for vacuuming the inside of the main body 2, and the like, and a cart 5 on which the main body 2 and the external device 4 are mounted and integrally movable. However, in the NMR analysis apparatus 1 according to the present embodiment, the cart 5 is not essential, and the main body 2 and the external device 4 may be installed on a floor surface.

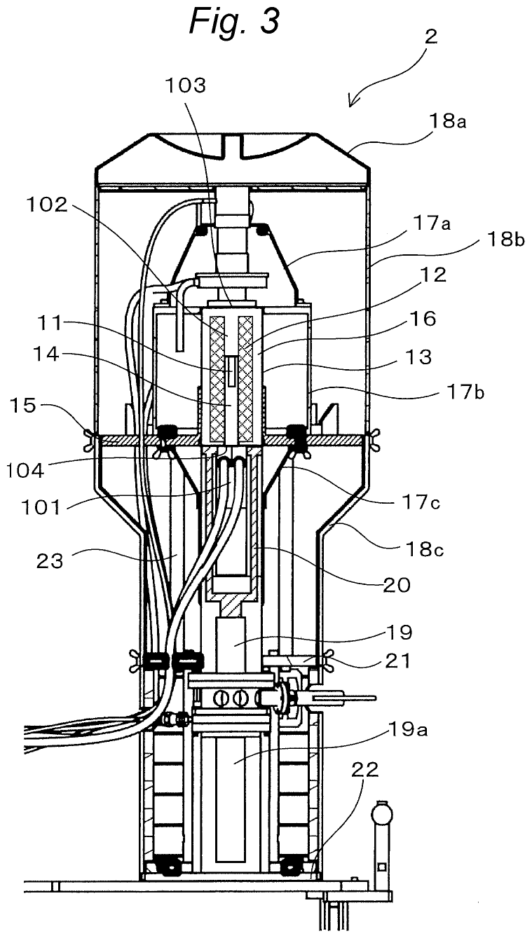

First, the main body 2 of the NMR analysis apparatus 1 will be described below. FIG. 3 is a cross-sectional view showing particularly a periphery of the main body 2 of the NMR analysis apparatus 1.

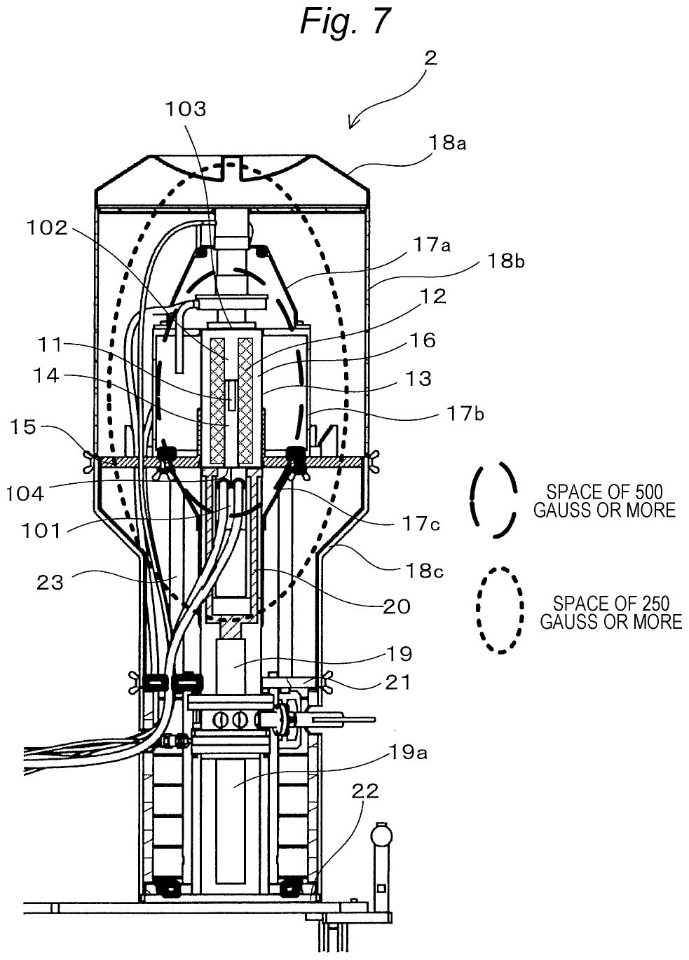

As shown in FIG. 3, the main body 2 includes a sample container 11 that contains the sample to be analyzed, a superconductor 12 having a cylindrical shape and disposed around the sample container 11, a storage container 13 having a cylindrical shape as well and housing the superconductor 12, a probe 14 that emits an electromagnetic wave at the sample in the sample container 11 and detects a nuclear magnetic resonance signal (NMR signal) from the sample, a stay (upper fixing member) 15 having a disk shape and disposed around the storage container 13, a vacuum thermal insulation container 16 that thermally insulates the superconductor 12 by bringing inside of the storage container 13 into a vacuum state, strong-magnetic-field protection members (first protective covers) 17a to 17c that are protective covers disposed so as to surround a space of a strong magnetic field in which a strength of a magnetic field generated outside of the storage container 13 by the superconductor 12 is equal to or greater than a first threshold value, weak-magnetic-field protection members (second protective covers) 18a to 18c that are protective covers disposed so as to surround a space of a weak magnetic field in which a strength of a magnetic field generated outside of the strong-magnetic-field protection members 17a to 17c by the superconductor 12 is equal to or greater than a second threshold value, a cold head 19 of a refrigerator 19a that expands a compressed refrigerant (for example, He gas, Ne gas, H gas, N gas, or gas obtained by liquefying these gases) supplied from the external device 4 to generate cold, a heat transfer body 20 for transferring the cold generated in the cold head 19 of the refrigerator 19a to the superconductor 12, a middle fixing member 21 and lower fixing member 22 having a disk shape, disposed around the storage container 13 and below the stay 15, and fixing the weak-magnetic-field protection members 18a to 18c together with the stay 15, a fixing support 23 for supporting the main body 2, and a probe adjuster 24 (refer to FIG. 2) that is attached to the fixing support 23 and adjusts (tunes) a characteristic of the probe 14 by receiving operation by an operator. The stay 15 is held at a predetermined position (height) from a lower end of the storage container 13 by the fixing support 23. In the present embodiment, the respective strong-magnetic-field protection members 17a to 17c and weak-magnetic-field protection members 18a to 18c are divided into three parts. However, the strong-magnetic-field protection members 17a to 17c may be an integrated protective cover, and the weak-magnetic-field protection members 18a to 18c may be an integrated protective cover. As shown in FIG. 1, a window 25 formed by a transmissive member is provided on a side surface of the main body 2. The window 25 is for the operator to visually recognize inside of the main body 2. An opening and closing door 26, which is opened and closed when the probe adjuster 24 is operated as will be described later, is provided below the window 25. The probe adjuster 24 is attached to outside of a space of 500 gauss or more as shown in FIG. 7. In the present embodiment, the probe adjuster 24 is attached to outside of the space of 500 gauss or more and inside of the weak-magnetic-field protection members 18a to 18c, and covered with the opening and closing door 26 so that the operator does not touch the probe adjuster 24 after adjustment. However, this disclosure is not limited to this configuration, and other configurations are possible. As an example, an inexpensive configuration can be considered in which the probe adjuster 24 is embedded in the weak-magnetic-field protection members 18a to 18c, and dials 32a to 32d of the probe adjuster 24 are exposed toward outside of the weak-magnetic-field protection members 18a to 18c.

Although not described, the main body 2 also includes various devices and members necessary for analysis of a sample by the NMR analysis apparatus 1.

Hereinafter, each component included in the main body 2 will be described in order.

The storage container 13 is, for example, a sealed, substantially cylindrical container. The storage container 13 has a communication space 101 that penetrates the storage container 13 in a radial direction between the weak-magnetic-field protection member 18a and the cold head 19 of the refrigerator 19a. A room-temperature bore space 102 extending in an axial direction of the storage container 13 is provided around a central axis of the storage container 13. A first opening 103 directed toward the weak-magnetic-field protection member 18a is provided at one end of the room-temperature bore space 102, and a second opening 104 opened to the communication space 101 is provided at another end of the room-temperature bore space 102. The room-temperature bore space 102 and the communication space 101 are partitioned and spatially isolated from an internal space of the storage container 13. By keeping the internal space of the storage container 13 in a vacuum state, the internal space of the storage container 13 is thermally isolated from the room-temperature bore space 102 and the communication space 101, and the storage container 13 becomes the vacuum thermal insulation container 16. In a case where the NMR analysis apparatus 1 is used, after a sample of various kinds, such as an organic compound, inorganic compound, and biological substance in various fields such as the pharmaceutical field, the biotechnology field, and the material field, is contained in the sample container 11, the weak-magnetic-field protection member 18a is removed, and the sample container 11 is inserted into the room-temperature bore space 102 of the storage container 13 from the first opening 103 toward the superconductor 12. Then, the NMR analysis apparatus 1 according to the present embodiment emits a pulsed electromagnetic wave with the probe 14, on the sample container 11 disposed in a static magnetic field generated by the superconductor 12 to excite nuclear magnetic resonance, and detects a nuclear magnetic resonance signal generated by the nuclear magnetic resonance, thereby analyzing a crystal structure of the sample in the sample container 11. Note that, although not shown, a monitor for displaying results of these analyses, a storage for storing the analysis results, a keyboard, a mouse, and the like for an operating person to perform operations are also connected to the NMR analysis apparatus 1.

Meanwhile, the superconductor 12 corresponds to a magnetic field generation source (magnetic pole) in the NMR analysis apparatus 1, and generates a static magnetic field for analyzing the sample. As the superconductor 12, a superconducting bulk magnet, particularly a high-temperature superconducting bulk magnet having a relatively high superconducting transition temperature (critical temperature), is used for a purpose of being able to generate a strong static magnetic field having excellent stability and enabling downsizing of the apparatus. For example, a RE-Ba—Cu—O (RE is a rare-earth element including Y)-based superconductor which is a high-temperature oxide superconductor is desirable. However, the superconductor 12 is not limited to the example described above, and may be an Nd-based, Sm-based, or Gd-based superconducting bulk magnet. In addition, a material other than a high-temperature superconducting bulk magnet may be used as long as it can be maintained at a superconducting transition temperature or lower.

Then, the superconductor 12 according to the present embodiment is formed in a cylindrical shape so as to surround the sample container 11 as shown in FIG. 3, and is disposed in the storage container 13 having a cylindrical shape as well. In particular, in the present embodiment, the superconductor 12 is formed by stacking a plurality of (for example, 3 to 10) cylindrical superconducting bulk magnets along the axial direction. However, the superconductor 12 may be formed of one superconducting bulk magnet instead of a plurality of superconductors. As will be described later, the superconductor 12 is thermally connected to the cold head 19 of the refrigerator 19a via the heat transfer body 20, so that cold generated by the cold head 19 of the refrigerator 19a can be transferred to the superconductor 12.

In addition, although the superconducting bulk magnet described above does not need to be energized to maintain a magnetic field, it is necessary to perform the following magnetization process as described in (1) to (3) in advance.

### (1) Magnetic Field Application Step

A magnetic field is applied to a superconductor by an external magnetic field generation device (hereinafter, referred to as a magnetization device) so that, at a temperature higher than a superconducting transition temperature (critical temperature) of the superconductor 12, a magnetic field in which a magnetic flux passes in the axial direction is generated in an inner peripheral space of the superconductor 12.

### (2) Magnetic Field Cooling Step

The superconductor 12 to which the magnetic field is applied as described above by the magnetization device is cooled to a temperature TO equal to or lower than the superconducting transition temperature. Specifically, the refrigerator 19a is operated while the magnetic field is applied to the superconductor 12 by operation of the magnetization device. As a result, the refrigerator 19a generates the cold, and the generated cold is transmitted via the cold head 19 to the superconductor 12 thermally connected to the cold head 19. As a result, the superconductor 12 is cooled to the temperature TO equal to or lower than the superconducting transition temperature. Thereafter, the superconductor 12 is maintained in a cooled state.

### (3) Demagnetization Step

Operation of the magnetization device is stopped while the temperature of the superconductor 12 is maintained at the temperature TO. As a result, the magnetic field applied to the superconductor 12 cooled to a temperature equal to or lower than the superconducting transition temperature (that is, brought into a superconducting state) is removed. Then, a superconducting current is induced in the superconductor 12 so as to restore a state of the magnetic field in response to a change in magnetic field strength associated with the removal of the applied magnetic field. The superconducting current is a circular current flowing in a plane perpendicular to a central axis of the superconductor 12, around the central axis of the superconductor 12. The superconducting current induced in this manner flows in the superconductor 12 to generate a magnetic field. That is, the superconductor 12 is magnetized. The magnetic field generated by the magnetization of the superconductor 12 is basically the same magnetic field as the applied magnetic field generated by the operation of the magnetization device. That is, when the superconducting current flows in the superconductor 12, the superconductor 12 traps the applied magnetic field generated by the operation of the magnetization device. When the superconductor 12 traps the applied magnetic field, a magnetic field (trapped magnetic field) through which a magnetic flux passes in the axial direction is formed in the inner peripheral space of the superconductor 12. Because the sample container 11 is positioned in the inner peripheral space of the superconductor 12 in which the trapped magnetic field is generated, the sample can be disposed in the static magnetic field. Thus, as described above, it is possible to analyze the sample placed in the strong static magnetic field by applying the electromagnetic wave to the sample from the probe 14.

Note that, after the magnetization process in (1) to (3) are performed, it is possible to maintain a state (superconducting characteristic) in which a strong magnetic field is generated for a long time, by maintaining the magnetized superconductor 12 at a temperature equal to or lower than the superconducting transition temperature by using the cold head 19 of the refrigerator 19a and the heat transfer body 20. In a case where the strong magnetic field is lost thereafter due to a temperature rise or the like, also, it is possible to restore the state in which the strong magnetic field is generated by performing the above-described magnetization process again.

The storage container 13 has a long cylindrical shape as shown in FIGS. 2 and 3, and stores the above-described superconductor 12 particularly around the sample container 11 near a top thereof. The heat transfer body 20 to be described later is housed in a central portion of the storage container 13, and the cold head 19 of the refrigerator 19a is housed below the storage container 13. The stay 15, the middle fixing member 21, and the lower fixing member 22 are disposed around the storage container 13. The refrigerator 19a and the cold head 19 are fixed to and supported by the cart 5. The heat transfer body 20 is supported by and fixed to the cold head 19 of the refrigerator 19a. The heat transfer body 20 is provided inside the storage container 13 and at a position surrounding the communication space 101. The superconductor 12 is supported by and fixed to the heat transfer body 20. The superconductor 12 is provided inside the storage container 13 and at a position surrounding the room-temperature bore space 102.

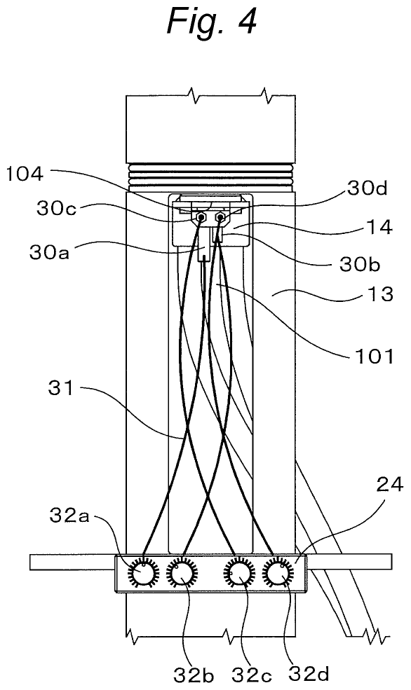

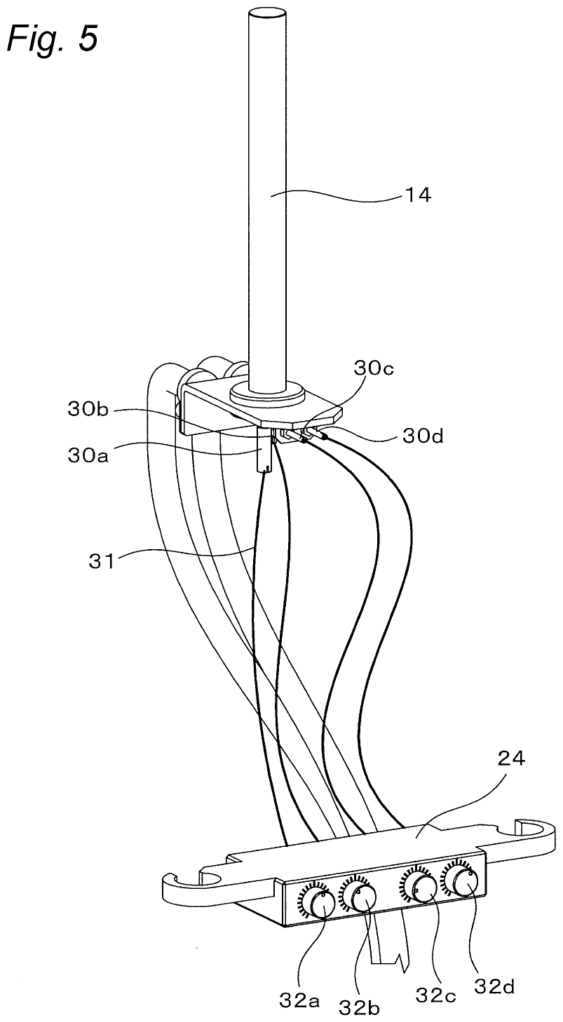

The probe 14 has a cylindrical shape, is thinner than the room-temperature bore space 102 of the storage container 13, and is fitted by being inserted through the communication space 101 and the second opening 104 into the room-temperature bore space 102 formed near the central axis of the storage container 13. As shown in FIG. 3, the fitted probe 14 is positioned in an internal space of the superconductor 12 having a cylindrical shape, that is, in the static magnetic field generated by the superconductor 12. FIG. 4 is a view showing the probe 14 fitted in the storage container 13. FIG. 5 is an extracted view of the probe 14 and the probe adjuster 24 connected to the probe 14, of the NMR analysis apparatus 1.

Here, the probe 14 includes, for example, a high-frequency generator that generates an electromagnetic wave, a coil that emits the electromagnetic wave at the sample container 11 and through which a nuclear magnetic resonance signal (NMR signal) from the sample container 11 flows, a detector that amplifies and detects the nuclear magnetic resonance signal flowing through the coil, a controller that controls these components, and the like. Then, the electromagnetic wave generated by the high-frequency generator is emitted at the sample, and a nuclear magnetic resonance signal from the sample is detected. Thereafter, the detected nuclear magnetic resonance signal converts a signal, which is a time-axis function, into a frequency function by using Fourier transform. Then, the nuclear magnetic resonance signal is finally stored as an NMR spectrum in a computer connected to the outside, and can be displayed on a monitor or the like.

Meanwhile, a main body of the probe 14 includes adjustment shafts 30a to 30d for adjusting (tuning) a characteristic of the probe. The adjustment shaft 30a is connected to a dial 32a of the probe adjuster 24 described later, by a connection mechanism, such as a wire 31 for example, to which rotational force can be applied. As a result, when the operator rotates the dial 32a, the rotational force is transmitted to the adjustment shaft 30a via the wire 31, and the adjustment shaft 30a can be rotated. Therefore, the operator can remotely operate the adjustment shaft 30a by rotating the dial 32a. Similarly, the adjustment shaft 30b is connected to a dial 32b of the probe adjuster 24, the adjustment shaft 30c is connected to a dial 32c of the probe adjuster 24, and the adjustment shaft 30d is connected to a dial 32d of the probe adjuster 24.

The adjustment of the characteristic of the probe 14 by the adjustment shafts 30a to 30d is, for example, an action of matching a frequency at which an atomic nucleus resonates in the nuclear magnetic resonance phenomenon with a frequency of a pulse output from the probe. Specifically, capacitance to each of a tuning capacitor and a matching capacitor is changed to perform adjustment so that reflection of an irradiation signal at a resonant frequency is minimized. It is also possible to perform drift correction on the superconductor 12 (for example, adjustment of an amplification factor or phase of a lock signal), and sensitivity and resolution of the spectrum are improved by the adjustment. For example, it is assumed that the electric capacitance of the capacitors is adjusted by using the adjustment shaft 30a and the adjustment shaft 30b, and drift correction is performed by using the adjustment shaft 30c and the adjustment shaft 30d. If these adjustments are not appropriately performed, a signal-to-noise ratio may be degraded and a required pulse width will increase. Therefore, for example, at a time of initial installation or periodic maintenance of the NMR analysis apparatus 1, the operator performs adjustment while checking the NMR spectrum displayed on the monitor by using a sample for adjustment or the like. At that time, the operator does not need to directly operate the adjustment shafts 30a to 30d, and can work by operating the dials 32a to 32d of the probe adjuster 24 at a distant position.

Here, as will be described later, the probe 14 is in the space of the strong magnetic field where the strength of the magnetic field is equal to or greater than the first threshold value, but the probe adjuster 24 is in the space of the weak magnetic field where the magnetic field is less than the first threshold value and equal to or greater than the second threshold value, which is weaker than the first threshold value. Therefore, it is possible to prevent a metal object worn or possessed by the operator from being attracted, and malfunction of a precision instrument.

Meanwhile, the stay 15 has a disk shape and is formed of a non-magnetic material (for example, a resin material, titanium, aluminum, or the like), and is disposed around the storage container 13. A large number of screw holes and the like are formed in the stay 15, and correspond to fixing members used for fixing the strong-magnetic-field protection members 17a to 17c and the weak-magnetic-field protection members 18a to 18c, which will be described later, to the main body 2.

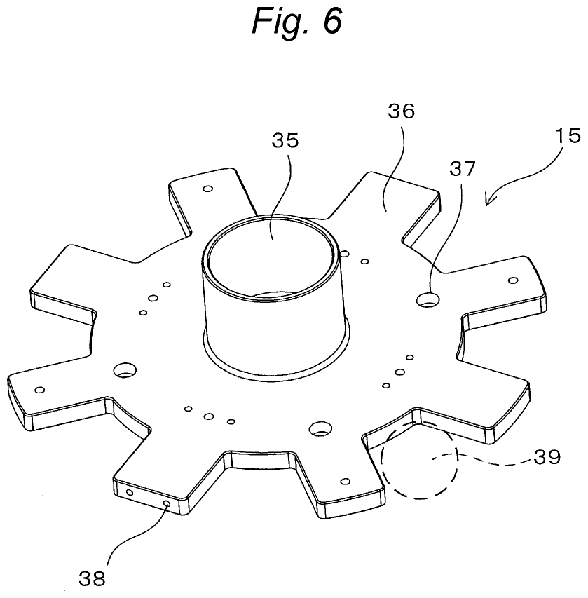

As shown in FIG. 6, the stay 15 includes a cylindrical portion 35 that surrounds an outer wall and outer periphery of the storage container 13, and flanges 36 extending in the radial direction from a lower end of the cylindrical portion 35. The cylindrical portion 35 has a cylindrical shape corresponding to the cylindrical shape of the storage container 13, and is disposed at a predetermined position (height) from the lower end of the storage container 13 so as to surround the outer wall and outer periphery of the storage container 13. An inner diameter of the cylindrical portion 35 is set to a length corresponding to an outer diameter of the storage container 13 (the inner diameter of the cylindrical portion 35 is slightly larger than the outer diameter of the storage container 13, and has a length that allows the storage container 13 to pass through inside of the cylindrical portion 35 and with which a relative position can be fixed unless load is applied). The stay 15 and the storage container 13 are fitted to each other by, for example, interference fit at the cylindrical portion 35. However, before the fitting, the stay 15 is movable in the axial direction with respect to the storage container 13 (a position of the stay 15 in a height direction can be adjusted) by applying load. The position of the stay 15 (position from the lower end of the storage container 13) is finally determined by the operator fitting the fixing support 23.

As shown in FIG. 6, a large number of screw holes 37 are formed in the flanges 36 in the axial direction (vertical direction). Screw holes 38 are formed in outer peripheral surfaces of the flanges 36 in the radial direction. Here, as shown in FIG. 3, the screw holes 37 in the axial direction are used to fix the strong-magnetic-field protection members 17a to 17c. Specifically, the strong-magnetic-field protection member 17a and the strong-magnetic-field protection member 17b are fixed to an upper side of the stay 15 by screws (however, the strong-magnetic-field protection member 17a is not directly fixed to the stay 15, but is fixed via the strong-magnetic-field protection member 17b), and the strong-magnetic-field protection member 17c is fixed to a lower side of the stay 15 by screws.

As shown in FIG. 6, the screw holes 38 in the radial direction are used to fix the weak-magnetic-field protection members 18a to 18c. Specifically, the weak-magnetic-field protection member 18a and the weak-magnetic-field protection member 18b are fixed to the upper side of the stay 15 by screws (however, the weak-magnetic-field protection member 18a is not directly fixed to the stay 15, but is fitted as a lid to a top of the weak-magnetic-field protection member 18b), and the weak-magnetic-field protection member 18c is fixed to the lower side of the stay 15 by screws. The weak-magnetic-field protection member 18c is also fixed by screws to the middle fixing member 21 and lower fixing member 22 positioned below the stay 15.

Meanwhile, as shown in FIG. 6, as viewed from above, the flanges 36 form a gear shape having a plurality of gaps 39 between teeth. The gaps 39 may be passages of cables and pipes running between the upper side and lower side of the stay 15 inside the main body 2. Because there are the plurality of gaps 39 in the radial direction, gaps 39 through which the cables and pipes that run can be freely selected according to positions of the cables and pipes. As a result, as shown in FIGS. 2 and 3, the cables and pipes connected to an upper portion of the storage container 13 can be taken out from the lower end of the main body 2. Note that a shape other than the gear shape may be applied as long as the shape has gaps 39 through which cables and pipes can pass.

Meanwhile, the vacuum thermal insulation container 16 is disposed inside the storage container 13. The above-described superconductor 12 is disposed further inside the vacuum thermal insulation container 16. The vacuum thermal insulation container 16 has an internal space, and the internal space is in a vacuum state. By bringing the internal space into a vacuum state, it is possible to thermally insulate the superconductor 12 disposed inside.

The strong-magnetic-field protection members 17a to 17c are formed of a non-magnetic material (for example, a resin material, titanium, aluminum, or the like), and are protective covers disposed so as to surround the space of the strong magnetic field in which the strength of the magnetic field generated outside the storage container 13 by the superconductor 12 is equal to or greater than the first threshold value. Here, the first threshold value is, for example, 500 gauss. The space of the strong magnetic field in which the strength of the magnetic field is equal to or greater than the first threshold value corresponds to a space that requires prohibition of any magnetic material approaching the superconductor 12. As shown in FIG. 7, the strong-magnetic-field protection members 17a to 17c surround the space of the strong magnetic field in which the strength of the magnetic field is equal to or greater than the first threshold value, by which it is possible to reliably prevent entry of a metal object worn or possessed by the operator into the area. Note that the strong-magnetic-field protection members 17a to 17c may surround an area larger than the space of the strong magnetic field in which the strength of the magnetic field generated by the superconductor 12 is equal to or greater than the first threshold value, as long as the strong-magnetic-field protection members 17a to 17c can at least surround the space of the strong magnetic field. However, for a purpose of reducing a size of the apparatus, the size is preferably as small as possible while satisfying a condition that the strong-magnetic-field protection members 17a to 17c surround the space of the strong magnetic field in which the strength of the magnetic field is equal to or greater than the first threshold value.

The weak-magnetic-field protection members 18a to 18c are formed of a non-magnetic material (for example, a resin material, titanium, aluminum, or the like) as well, and are protective covers disposed so as to surround the space of the weak magnetic field in which the strength of the magnetic field generated outside of the strong-magnetic-field protection members 17a to 17c by the superconductor 12 is equal to or greater than the second threshold value. Here, the second threshold value is, for example, 250 gauss. The space of the weak magnetic field in which the strength of the magnetic field is equal to or greater than the second threshold value corresponds to a space that requires prohibition of any precision instrument approaching the superconductor 12. As shown in FIG. 7, the weak-magnetic-field protection members 18a to 18c surround the space of the weak magnetic field in which the strength of the magnetic field is equal to or greater than the second threshold value, by which it is possible to reliably prevent entry of precision instrument worn or possessed by the operator into the area. Note that the weak-magnetic-field protection members 18a to 18c may surround an area larger than the space of the weak magnetic field in which the strength of the magnetic field generated by the superconductor 12 is equal to or greater than the second threshold value, as long as the weak-magnetic-field protection members 18a to 18c can at least surround the space of the weak magnetic field. However, for a purpose of reducing a size of the apparatus, the size is preferably as small as possible while satisfying a condition that the weak-magnetic-field protection members 18a to 18c surround the space of the weak magnetic field in which the strength of the magnetic field is equal to or greater than the second threshold value. As a result, in the present embodiment, as shown in FIG. 1, the main body 2 has a larger diameter on an upper side thereof than on a lower side thereof (has an inverted triangle shape).

In the present embodiment, after the superconductor 12 is magnetized and the strong-magnetic-field protection members 17a to 17c and the weak-magnetic-field protection members 18a to 18c are fitted to the stay 15, the strong-magnetic-field protection members 17a to 17c and the weak-magnetic-field protection members 18a to 18c basically remain mounted all the time until it is necessary to magnetize the superconductor 12 again (however, the weak-magnetic-field protection member 18a may be removed when a sample is set into the sample container 11). Therefore, it is possible to prevent entry of a metal object or precision instrument worn or possessed by the operator, from every direction into an area of a magnetic field having a strength equal to or greater than the first threshold value, or equal to or greater than the second threshold value not only at a time of use of the NMR analysis apparatus 1 needless to say, but also until work of exterior assembly at a time of transportation or installation, periodic maintenance, storage, or the like when the NMR analysis apparatus 1 is not in use is completed.

The probe 14 is positioned inside the strong-magnetic-field protection members 17a to 17c, that is, in the space of the strong magnetic field in which the strength of the magnetic field is equal to or greater than the first threshold value. Meanwhile, the probe adjuster 24 is positioned outside the strong-magnetic-field protection members 17a to 17c where the magnetic field is weaker and inside the weak-magnetic-field protection members 18a to 18c, that is, in the space of the weak magnetic field in which the strength of the magnetic field is less than the first threshold value and equal to or greater than the second threshold value. Therefore, in a case of adjusting (tuning) the characteristic of the probe 14 as described above, the adjustment can be performed by operation of the probe adjuster 24. Therefore, it is possible to prevent entry of a metal object or precision instrument worn or possessed by the operator, from every direction into at least an area of a magnetic field having a strength equal to or greater than the first threshold value until work is completed.

Meanwhile, the refrigerator 19a is a device that is airtightly fixed below the storage container 13 and expands a compressed refrigerant (for example, He gas, Ne gas, H gas, N gas, or gas obtained by liquefying these gases) supplied from the external device 4 to cause the cold head 19 stored in the storage container 13 to generate cold. A type of the refrigerator is not limited, but the refrigerator is desirably as small as possible, and is a device capable of generating cold for cooling at least the superconductor 12 to a superconducting transition temperature (critical temperature) or lower. Examples of the refrigerator include a GM refrigerator, a Stirling refrigerator, a pulse tube refrigerator, and the like. As an example, the pulse tube refrigerator is a refrigerator that generates cold by generating a periodic pressure vibration in a pulse tube and expanding and contracting a so-called gas piston in the pulse tube. As long as the refrigerator can generate cold necessary for the cold head 19, a refrigerator other than the refrigerator according to the present embodiment can be used.

Meanwhile, the heat transfer body 20 has one end thermally connected to the cold head 19 of the refrigerator 19a and another end thermally connected to the superconductor 12, and transfers the cold generated in the cold head 19 of the refrigerator 19a to the superconductor 12. The heat transfer body 20 is formed of a non-magnetic material (for example, copper) having high thermal conductivity. A vacuum state is maintained around the cold head 19 of the refrigerator 19a and the heat transfer body 20 for thermal insulation.

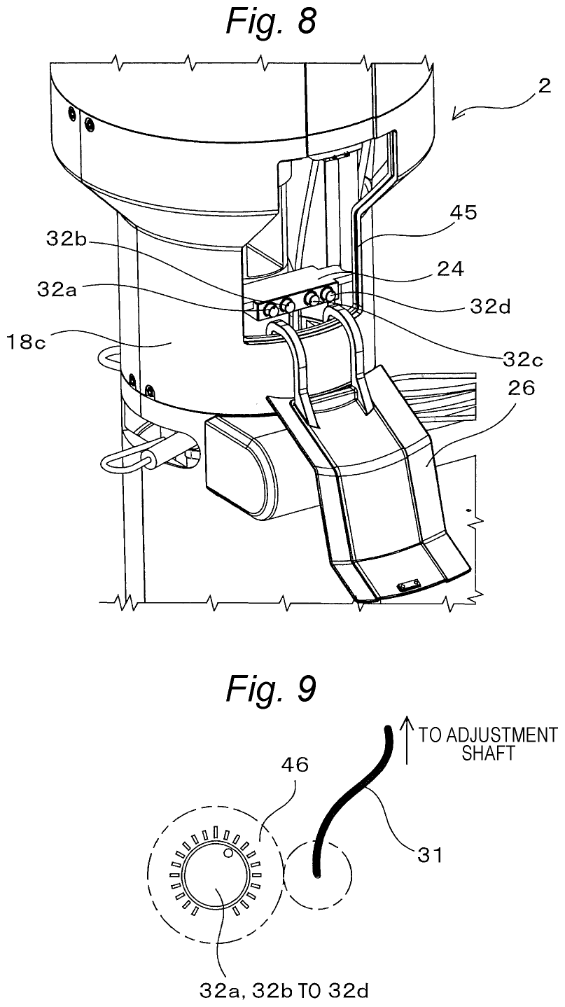

The probe adjuster 24 is an operation mechanism that adjusts the characteristic of the probe 14 by receiving operation by the operator, and, as shown in FIG. 2, is fixed to the fixing support 23, outside the strong-magnetic-field protection members 17a to 17c and inside the weak-magnetic-field protection members 18a to 18c as described above. A position at which the probe adjuster 24 is fixed is particularly in vicinity of the opening and closing door 26 (that is, an opening 45 opened by opening the opening and closing door 26) formed in the weak-magnetic-field protection member 18c, particularly at a position facing (corresponding to) the opening 45 at the same height as the opening 45. FIG. 8 is a view showing a periphery of opening 45 of main body 2 in a state where the opening and closing door 26 is opened.

As shown in FIG. 8, the probe adjuster 24 is at a position facing particularly the opening 45, that is, at a position close to the opening 45 when the opening and closing door 26 is opened. Therefore, the operator can visually recognize the dials 32a to 32d from the opening 45 and can easily operate the dials 32a to 32d from the opening 45 by hand. For example, adjustment can be easily performed while checking the NMR spectrum displayed on the monitor.

As shown in FIG. 4, scales each indicating a reference position (0 position) for each of the dials 32a to 32d and an amount of operation from each of the reference positions are drawn on the probe adjuster 24, and the characteristic of the probe is adjusted according to the operation amount of the dials from the reference position. Content of the adjustment can be clearly specified by a numerical value of the scales. For example, if the adjusted content is recorded as “2” to the right, “3” to the left, or the like, the adjustment content can be shared among a plurality of operators, making readjustment work easier. In the example shown in FIG. 4, the 12:00 direction is the reference position. Note that, for easy visual recognition of the operation amount, a display may be provided for displaying the reference positions for the dials 32a to 32d and amount of operation from the reference positions in numerals (−5 to 0 to +5, for example).

As described above, the adjustment shafts 30a to 30d are connected to the dials 32a to 32d on the probe adjuster 24 via the wires 31, and when the operator rotates the dials 32a to 32d, rotational force thereof is transmitted to the adjustment shafts 30a to 30d via the wires 31 by which the adjustment shafts 30a to 30d can be rotated. Rotation angles of the dials 32a to 32d on the probe adjuster 24 and rotation angles of the adjustment shafts 30a to 30d may or may not match with each other. As a case of not matching, as shown in FIG. 9, a step-up device 46 (or may be a reduction device) that changes a rotation ratio may be incorporated into each of the dials 32a to 32d. Thus, for example, the adjustment shafts 30a to 30d are rotated by an angle greater or smaller than a predetermined angle by rotating the dials 32a to 32d by the predetermined angle. By adjusting a gear ratio of the step-up device 46, rotation amounts of the adjustment shafts 30a to 30d with respect to the dials 32a to 32d can be appropriately adjusted. As a result, for example, even in a specification in which a variable capacitor, a variable resistor, or the like integrated with the adjustment shafts 30a to 30d requires an adjustment margin of one rotation or more, the dials 32a to 32d can be adjusted by one rotation or less.

The window 25 is disposed on a side surface of the main body, and is formed of, for example, a transmissive member in order for the operator to visually recognize inside of the main body 2. The operator can check an internal state of the main body 2 through the window 25.

The opening and closing door 26 includes, for example, a hinge or the like, and has a structure openable and closable by the operator. As shown in FIG. 8, the characteristic of the probe 14 can be adjusted from the opening 45 by opening the opening and closing door 26. Therefore, it is not necessary to remove the weak-magnetic-field protection members 18a to 18c for adjustment of the probe 14. The opening and closing door 26 is closed and sealed off with a seal or the like, except when the characteristic of the probe 14 is adjusted. As a result, it is possible to reduce chances to come into contact with the probe adjuster 24 except for in a situation where the characteristic of the probe 14 is adjusted, and to prevent an adjusted state from being lost due to erroneous operation. In the configuration described above (that is the configuration in which the probe adjuster 24 is embedded in the weak-magnetic-field protection members 18a to 18c, and the dials 32a to 32d of the probe adjuster 24 are exposed toward outside of the weak-magnetic-field protection members 18a to 18c), it is also conceivable to cover the entire dials 32a to 32d with a separate cover after adjustment of the dials 32a to 32d, in order to prevent erroneous operation by the operator.

Next, with reference back to FIG. 1, the external device 4 of the NMR analysis apparatus 1 will be described. The external device 4 is connected to the main body 2 described above through the pipe 3 or the cable, and includes the compressor that supplies the refrigerant for cooling the superconductor 12, the pump for vacuuming the inside of the main body 2, and the like, Note that, for example, a compressed refrigerant (for example, He gas, Ne gas, H gas, N gas, or gas obtained by liquefying these gases) is supplied from the external device 4, and the supplied refrigerant is expanded to generate cold in the refrigerator 19a of the main body 2. Note that, although the main body 2 and the external device 4 are separated from each other in the present embodiment, the external device 4 may be disposed in the main body 2.

Finally, the cart 5 of the NMR analysis apparatus 1 will be described with reference to FIG. 1. The cart 5 includes a pedestal 41 on which the main body 2 and the external device 4 are placed, wheels 42 attached to a bottom surface of the pedestal 41, and a handle 43 gripped by the operator. The operator can easily move the main body 2 and the external device 4 to any positions, for example, by gripping the handle 43 and applying the load. In particular, because the NMR analysis apparatus 1 of the present embodiment is smaller and lighter than a conventional apparatus, the NMR analysis apparatus 1 can be easily moved even by human power. The main body 2 and the external device 4 are fixed to the pedestal 41 by a fixing mechanism (for example, bolts or the like) (not shown), and the main body 2 and the external device 4 are basically operated on the cart 5, and are stored while being placed on the cart 5 even after the operation is finished. The wheels 42 include a lock mechanism also, and can fix the position of the NMR analysis apparatus 1 so that the NMR analysis apparatus 1 does not move during operation.

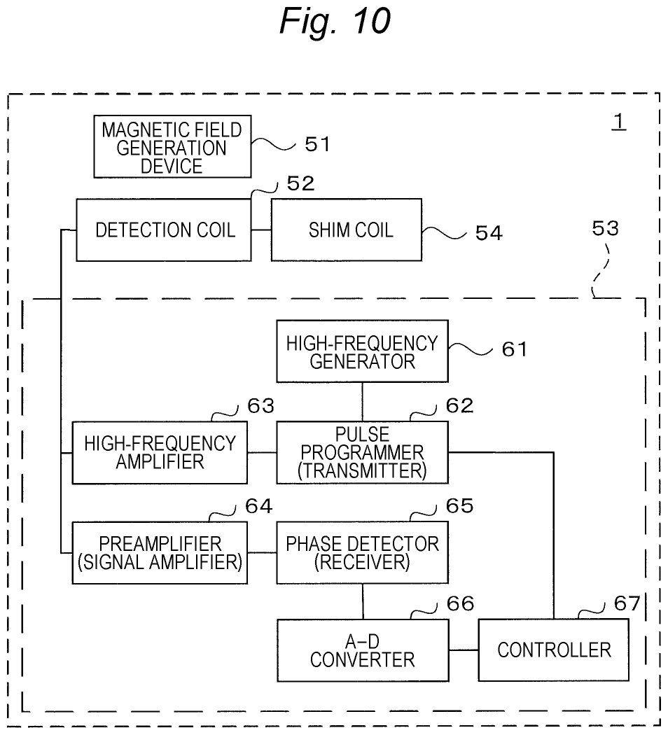

Next, a control configuration of the NMR analysis apparatus 1 having the above-described configuration will be briefly described. FIG. 10 is a diagram showing a schematic configuration of the NMR analysis apparatus 1.

The NMR analysis apparatus 1 includes a magnetic field generation device 51 for generating a magnetic field including the superconductor 12 and the refrigerator 19a described above, a detection coil 52, and an analysis mechanism 53. The detection coil 52 is disposed in the inner peripheral space of the superconductor 12, and the sample to be analyzed is placed on the inner peripheral side of the detection coil 52. A shim coil 54 is disposed on an outer peripheral side of the detection coil 52. The analysis mechanism 53 further includes a high-frequency generator 61, a pulse programmer (transmitter) 62, a high-frequency amplifier 63, a preamplifier (signal amplifier) 64, a phase detector (receiver) 65, an analog-digital (A-D) converter 66, and a controller 67.

In a state where the magnetic field generation device 51 is operated, a trapped magnetic field is formed in the inner peripheral space of the superconductor 12, as described above. Next, by adjusting the trapped magnetic field by the shim coil 54, uniformity of the magnetic field strength of the trapped magnetic field is improved. At this time, the trapped magnetic field is adjusted by the shim coil 54 so that the uniformity of the strength of the magnetic field in the space is 1 ppm or less. Then, after the uniformity of the strength of the magnetic field is improved, the sample is placed in the sample container 11 in the inner peripheral space of the superconductor 12. In this state, the high-frequency generator 61 is operated. Then, high-frequency pulses generated by the high-frequency generator 61 are sent to the detection coil 52 via the pulse programmer 62 and the high-frequency amplifier 63, and a pulse electromagnetic wave is emitted at the sample. By nuclear magnetic resonance that occurs when an electromagnetic wave is emitted at a sample placed in a magnetic field, a very small current flows through the detection coil 52 positioned around the sample. A signal (NMR signal) representing the very small current is transmitted to the controller 67 via the preamplifier 64, the phase detector 65, and the A-D converter 66. The controller 67 calculates an NMR spectrum on the basis of the transmitted NMR signal. A molecular structure of the sample is analyzed on the basis of the obtained NMR spectrum.

As described above in detail, the NMR analysis apparatus 1 according to the present embodiment includes a superconductor 12 that generates a magnetic field, a sample container 11 that is held in a magnetic field generated by the superconductor 12 and contains a sample to be analyzed, a probe 14 that emits an electromagnetic wave at the sample and detects a nuclear magnetic resonance signal from the sample, strong-magnetic-field protection members 17a to 17c that surround at least a space in which strength of a magnetic field generated by the superconductor 12 is equal to or greater than a first threshold value, weak-magnetic-field protection members 18a to 18c that are mounted outside of the strong-magnetic-field protection members 17a to 17c and surround at least a space in which strength of a magnetic field generated by the superconductor 12 is equal to or greater than a second threshold value that is weaker than the first threshold value, an opening 45 provided in the weak-magnetic-field protection members 18a to 18c, and a probe adjuster 24 that is disposed outside the strong-magnetic-field protection members 17a to 17c and inside the weak-magnetic-field protection members 18a to 18c, and in vicinity of the opening 45, and adjusts a characteristic of the probe 14 by receiving operation by an operator. Therefore, when adjusting the characteristic of the probe 14, it is possible to reliably prevent entry of a metal object or precision instrument worn or possessed by the operator into an area in which a strong magnetic field is generated. Meanwhile, because the weak-magnetic-field protection members 18a to 18c include the probe adjuster 24 therein, it is possible to reduce chances to come into contact with the probe adjuster 24 except for in a situation where the characteristic of the probe 14 is adjusted, and to prevent an adjusted state from being lost due to erroneous operation.

The probe adjuster 24 includes at least one operation unit (dials 32a to 32d) that is able to be operated by the operator, the characteristic of the probe 14 is adjusted by the operation unit being operated, and the probe adjuster 24 is disposed in a manner that the operation unit and the opening 45 are positioned to face each other. Therefore, the operator can easily operate the operation unit from the opening 45. It is also easy for the operator to perform adjustment while checking the NMR spectrum displayed on the monitor.

The scale indicating a reference position for the operation unit and an amount of operation from the reference position is drawn on the probe adjuster 24, and the characteristic of the probe 14 is adjusted according to the amount of operation from the reference position for the operation unit. Therefore, content of the adjustment can be clearly specified by a numerical value of the scale. For example, if the adjusted content is recorded as “2” to the right, “3” to the left, or the like, the adjustment content can be shared among a plurality of operators, making readjustment work easier.

In addition, the weak-magnetic-field protection members 18a to 18c include the opening and closing door 26 that opens and closes the opening 45. Therefore, it is possible to easily perform specific adjustment of the probe when the opening and closing door 26 is open. Meanwhile, it is possible to reduce chances to come into contact with the probe adjuster 24 when the opening and closing door 26 is closed, that is, except for in a situation where the characteristic of the probe 14 is adjusted, and to prevent an adjusted state from being lost due to erroneous operation.

Note that this disclosure is not limited to the above-described embodiments, and various improvements and modifications may be made without departing from the gist of this disclosure.

For example, in the present embodiment, the strong-magnetic-field protection members 17a to 17c surround the space of a strong magnetic field of 500 gauss or more around the superconductor 12, and the weak-magnetic-field protection members 18a to 18c surround the space of a weak magnetic field of 250 gauss or more around the superconductor 12. However, the strength of the magnetic field in the space to be surrounded can be appropriately changed. Shapes of the strong-magnetic-field protection members 17a to 17c and the weak-magnetic-field protection members 18a to 18c are not limited to the shapes shown in FIGS. 1 and 2.

In the present embodiment, the probe adjuster 24 includes the four dials 32a to 32d as the operation unit. The number of the dials 32a to 32d corresponds to the number of the adjustment shafts 30a to 30d included in the probe 14. Therefore, for example, if the number of the adjustment shafts included in the probe 14 is one, the number of the dials is also one.

In the present embodiment, the adjustment shafts 30a to 30d included in the probe 14 and the dials 32a to 32d included in the probe adjuster 24 are connected to each other by the wires 31, but may be connected by a mechanism other than wires, as long as the mechanism can transmit rotational force. For example, it is also possible to use a shaft connected by one or more universal joints. Alternatively, the adjustment shafts 30a to 30d and the dials 32a to 32d may be electrically connected to each other. For example, actuators driven according to operation of the dials 32a to 32d may be attached to the adjustment shafts 30a to 30d.

Furthermore, in the present embodiment, a nuclear magnetic resonance analysis apparatus that analyzes a structure of a sample by using a nuclear magnetic resonance phenomenon in particular has been described as an example of a nuclear magnetic resonance apparatus including a magnetic field generator. However, this disclosure can also be applied to a magnetic resonance imaging apparatus (MRI apparatus) that images information of an inside of a living body by using a nuclear magnetic resonance phenomenon.

A nuclear magnetic resonance apparatus includes a magnetic field generator that generates a magnetic field, a sample container that is held in a magnetic field generated by the magnetic field generator and contains a sample to be analyzed, a probe that emits an electromagnetic wave at the sample and detects a nuclear magnetic resonance signal from the sample, a first protective cover that surrounds at least a space in which strength of a magnetic field generated by the magnetic field generator is equal to or greater than a first threshold value, a second protective cover that is mounted outside of the first protective cover and surrounds at least a space in which strength of a magnetic field generated by the magnetic field generator is equal to or greater than a second threshold value that is weaker than the first threshold value, an opening provided in the second protective cover, and a probe adjuster that is disposed outside the first protective cover and inside the second protective cover, and in vicinity of the opening, and adjusts a characteristic of the probe by receiving operation by an operator.

The nuclear magnetic resonance apparatus having the above-described configuration according to this disclosure includes the first protective cover and the second protective cover around the magnetic field generator, and includes, outside the first protective cover, the probe adjuster for adjusting the characteristic of the probe. Therefore, when adjusting the characteristic of the probe, it is possible to reliably prevent entry of a metal object or precision instrument worn or possessed by the operator into an area in which a strong magnetic field is generated. Meanwhile, because the second protective cover includes the probe adjuster therein, it is possible to reduce chances to come into contact with the probe adjuster except for in a situation where the characteristic of the probe is adjusted, and to prevent an adjusted state from being lost due to erroneous operation.

In the nuclear magnetic resonance apparatus, the probe adjuster includes at least one operation unit that is able to be operated by the operator, the characteristic of the probe is adjusted by the operation unit being operated, and the probe adjuster is disposed in a manner that the operation unit and the opening are positioned to face each other.

According to the nuclear magnetic resonance apparatus having the above-described configuration according to this disclosure, the operator can easily operate the operation unit from the opening.

In the nuclear magnetic resonance apparatus, a scale indicating a reference position for the operation unit and an amount of operation from the reference position is drawn on the probe adjuster, and the characteristic of the probe is adjusted according to the amount of operation from the reference position for the operation unit.

According to the nuclear magnetic resonance apparatus having the above-described configuration according to this disclosure, content of the adjustment can be clearly specified by a numerical value of the scale. For example, if the adjusted content is recorded as “2” to the right, “3” to the left, or the like, the adjustment content can be shared among a plurality of operators, making readjustment work easier.

In the nuclear magnetic resonance apparatus, the second protective cover includes an opening and closing door that opens and closes the opening.

According to the nuclear magnetic resonance apparatus having the above-described configuration according to this disclosure, it is possible to easily perform specific adjustment of the probe when the opening and closing door is open. Meanwhile, it is possible to reduce chances to come into contact with the probe adjuster when the opening and closing door is closed, that is, except for in a situation where the characteristic of the probe is adjusted, and to prevent an adjusted state from being lost due to erroneous operation.

In the nuclear magnetic resonance apparatus, the sample container is inserted into the magnetic field from one side of the magnetic field generator, and the probe is inserted into the magnetic field from another side of the magnetic field generator.

In the nuclear magnetic resonance apparatus, the second protective cover includes a removable protection member on one side of the magnetic field generator, and the sample container is inserted into the magnetic field from one side of the magnetic field generator after the removable protection member is removed.

In the nuclear magnetic resonance apparatus, the second protective cover includes the opening on another side of the magnetic field generator.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

1. A nuclear magnetic resonance apparatus comprising:
a magnetic field generator configured to generate a magnetic field;
a sample container that is held in a magnetic field generated by the magnetic field generator and configured to contain a sample to be analyzed;
a probe configured to emit an electromagnetic wave at the sample and detect a nuclear magnetic resonance signal from the sample;
a first protective cover that surrounds at least a space in which strength of a magnetic field generated by the magnetic field generator is equal to or greater than a first threshold value;
a second protective cover that is mounted outside of the first protective cover and surrounds at least a space in which strength of a magnetic field generated by the magnetic field generator is equal to or greater than a second threshold value that is weaker than the first threshold value;
an opening provided in the second protective cover; and
a probe adjuster that is disposed outside the first protective cover and inside the second protective cover, and in vicinity of the opening, and configured to adjust a characteristic of the probe by receiving operation by an operator.

2. The nuclear magnetic resonance apparatus according to claim 1, wherein
the probe adjuster includes at least one operation unit that is able to be operated by an operator,
a characteristic of the probe is adjusted by the operation unit being operated, and
the probe adjuster is disposed in a manner that the operation unit and the opening are positioned to face each other.

3. The nuclear magnetic resonance apparatus according to claim 2, wherein
a scale indicating a reference position for the operation unit and an amount of operation from the reference position is drawn on the probe adjuster, and
a characteristic of the probe is adjusted according to an amount of operation from a reference position for the operation unit.

4. The nuclear magnetic resonance apparatus according to claim 1, wherein the second protective cover includes an opening and closing door configured to open and close the opening.

5. The nuclear magnetic resonance apparatus according to claim 2, wherein the second protective cover includes an opening and closing door configured to open and close the opening.

6. The nuclear magnetic resonance apparatus according to claim 3, wherein the second protective cover includes an opening and closing door configured to open and close the opening.

7. The nuclear magnetic resonance apparatus according to claim 1, wherein
the sample container is inserted into the magnetic field from one side of the magnetic field generator, and
the probe is inserted into the magnetic field from another side of the magnetic field generator.

8. The nuclear magnetic resonance apparatus according to claim 7, wherein
the second protective cover includes a removable protection member on one side of the magnetic field generator, and
the sample container is inserted into the magnetic field from one side of the magnetic field generator after the removable protection member is removed.

9. The nuclear magnetic resonance apparatus according to claim 8, wherein
the second protective cover includes the opening on another side of the magnetic field generator.
